(19) United States
(12) Patent Application Publication
(10) Pub. No.: US 2014/0150859 A1
(43) Pub. Date: Jun. 5, 2014

(54) IONICALLY RECONFIGURABLE ORGANIC PHOTOVOLTAIC AND PHOTONIC DEVICES WITH TUNABLE COMMON ELECTRODE

(71) Applicant: The Board of Regents of the University of Texas System, Austin, TX (US)

(72) Inventors: Anvar A. Zakhidov, McKinney, TX (US); Alexander Cook, Flower Mound, TX (US); Jonathan Yuen, Dallas, TX (US); Alexios Papadimitratos, McKinney, TX (US)

(73) Assignee: The Board of Regents of the University of Texas System, Austin, TX (US)

(21) Appl. No.: 14/094,580

(22) Filed: Dec. 2, 2013

Related U.S. Application Data
(60) Provisional application No. 61/732,379, filed on Dec. 2, 2012.

(51) Int. Cl. H01L 51/44; H01G 11/08

(52) U.S. Cl. CPC H01L 51/445; H01G 11/08
USPC 136/255; 257/40

(57) ABSTRACT

The present invention is directed to a novel type of monolithic hybrid technology. The invention is directed to photonic devices with a minimum of three (3) electrodes and by an inventive process for incorporating mobile ions into organic components of high performance organic photovoltaic (OPV) devices, organic photodetectors and other hybrid photonic devices (such as tandems of OPV), through a novel unique device architecture of a hybrid “Ionic-NT-OPV” structure, in which the ionic components are separated from the OPV by a common nanoporous charge collecting electrode (symbolically depicted as a nanotube: NT), permeable to ions of ionic component inside an inter-connected microchamber.

### CROSS-REFERENCES REGARDING RELATED APPLICATIONS

This Application claims the benefit under 35 U.S.C. §119(e) of U.S. Provisional Patent Application No. 61/732,379 filed Dec. 2, 2012 which is incorporated herein by reference in its entirety as if fully set forth herein.

### STATEMENT REGARDING FEDERALLY-SPONSORED RESEARCH OR DEVELOPMENT

This invention was made with government support under DOE Phase I and Phase II STTR Grant No. DE-SC 0003664 awarded by the Department of Energy. The government has certain rights in the invention.

### BACKGROUND OF THE INVENTION

The properties of many materials can be drastically changed by injecting electronic charges into their electronic bands via ionically-induced charging from a nearby electrolyte. Such electronic charging is electrostatically induced by ionic components, by ions of opposite charge located on the surface or at the interface of the material. This creates a double layer, with one layer of electronic carriers (in the solid material) and another layer being ionic charges in form of atomic or molecular ions at the interface with the solid. This electronic double layer charging (EDLC) has been demonstrated to modulate electronic and other properties at interfaces. EDLC modification of the electronic properties of semiconducting materials has been extensively utilized. Formation of a high density charge state on the surface of a semiconductor via EDLC was first pioneered by Frisbie et al. on organic semiconductors [1-7] and subsequently expanded on by Awaga et al. [8-16] in both polymeric and small molecular solids. Both groups have also done work on the effect of electrolyte type on charging behavior, with novel electrolytes such as ionic liquids, polymer electrolytes and ionic gels extensively studied. More EDLC studies have been done by Iwasa et al. on inorganic systems [17-21]. In particular, ion-gating of various inorganic materials, such as oxides, nitrates and similar by Iwasa et al. have resulted in the observation of various emergent phenomena, such as superconductivity, ferromagnetism and ambi-polarity.

Most of the studies mentioned previously have been performed on large size, typically crystalline bulk samples. In contrast, intrinsically low dimensional materials (1D and 2D materials) make up a large subset of materials have been discovered and developed in recent years, which possess properties which differ greatly from typical bulk materials. 1D materials include semiconducting and metallic nanotubes, nanowires and nanoribbons, such as carbon nanotubes (CNT), carbyne, silicon and silver nanowires, and graphene nanoribbons (GRN). Examples of 2D semiconducting materials include graphene, graphane, germanane, and various 2D chalcogenides (WO₂ and MoS₂, for example). The low dimensional nature of these materials results in a large surface area to volume ratio, a low density of states (DOS) and the existence of singularities in DOS, of which bulk materials rarely possess.

Low dimensional materials are therefore especially suited for EDLC, where their large surface areas maximize contact of the material to the electrolytic ionic species. More importantly, their low volumes and high porosity enable the charging effects to permeate the entire aerogel type material network via hierarchy of pores, completely changing the electronic properties of the nanostructured material. In many cases, the materials can be charged and dried, in which the captured in pores EDLC ionic species remain on the interfaces for an extended period of time, even when charging bias voltage V switched off. This has been shown specifically for carbon nanotubes (CNTs) by D. Suk, A. Zakhidov and R. Baughman [31] and discussed for other types of nanostructured materials. The EDLC-doped CNTs have strongly changed physical properties, such as increased electrical conductivity, and shifted Fermi level, and hence significantly changed work function. Since the amount of charge depends on the capacitance and applied voltage, the electrolytes which can sustain high charging voltages are essential. Of particular interest are ionic liquids, which have the highest recorded charging voltages thresholds (of up to 5V) and allows EDLC induced doping at higher level of dopants and hence with larger scale of properties modulation.

P- and n-type electronic doping of organic Donor and Acceptor transport layers has been shown to increase the performance of organic photovoltaic devices (OPVs) in p-i-n type structures with internal built-in potentials at p-i and i-n interfaces. Additionally, 8-10% efficiency has been achieved in OPV tandems, demonstrating great promise of P-I-N organic structures. This electronic doping improves the separation of positive and negative charges by built-in potentials, and it also decreases series resistance, thereby enhancing power conversion efficiency. However, such chemical doping is usually done in low molecular OPVs using air sensitive dopants, such as Cs or Na in a high vacuum process, which is very expensive, and cannot be used for polymeric bulk heterojunctions (BHJs).

Alternatively, using mobile ions as dopants in the organic layer of an OPV is a promising strategy to improve device efficiency while maintaining the simplicity of device fabrication. Recently similar devices exhibiting ionic diffusion in nanostructures, which change their electronic conductivity nonlinearly, have been described in terms of memristors or memristive behavior. Such mixed conductor devices, which have both ionic and electronic conductivity, are currently used in chemical sensing, electrochromic windows, fuel cells, batteries and optoelectronics. Mixed conducting devices are particularly promising for energy storage applications, where ionic current adds to electronic current and assists in electronic charge injection or collection between layers of the device.

It has been shown that diffusion of mobile ions in the layers of a hybrid PV made of n-Si coated by a polyaniline (PANi) film increases the PV performance. In particular, the photocurrent and open circuit voltage (Voc) increases under light excitation. This improvement correlates with photoelectrochemical doping of n-Si/(p-doped PANi). Similarly, an ionic OPV device based upon polyphenylene vinylene (PPV), and imbedded into it ionic component: polyethylene oxide (PEO) with lithium triflate was created by electrochemical doping by biasing the OPV and then freezing a charge-separated ionic distribution to create a P-I-N junction device. Arranging the ions in this way improved the device photocurrent by nearly two orders of magnitude and increased open circuit voltage. There have been reports of ionic homojunction OPVs based on PPV/PEO/salt mixtures in which mobile ions or fixed ionic distributions contribute to high open circuit voltage and variable short circuit current (I_{SC}) depending on dopant levels. Furthermore, similar PPV/PEO devices that are electrochemically doped by mixing an ionic reservoir into bulk heterojunction and stabilizing the ionic dopants by using polymerizable ions to lock in a P-I-N distribution have been investigated. Recently, a photovoltaic response from a bilayer mixed conducting device has been achieved. In this device, mobile ions created a dynamic p-n junction between the two mixed conductor layers, contributing to the photovoltaic behavior. However, the semiconductors and systems of materials explored to date are not optimal for high power conversion efficiency, peaking near 0.1% in the best reported case. In addition, for all of these systems, little characterization beyond current-voltage characteristics has been investigated. Therefore, the governing mechanisms of these ionic OPV devices' operation are not well established. To date, mixed conductor P-I-N OPVs have not been pursued using materials that give rise to the highest power conversion efficiencies, such as the P3HT/PCBM system.

On the other hand ionic liquids have been used recently as ionic gates to tune the operation of organic field effect transistors (OFET) by [16-21]. Various types of organic molecular layers have been shown to be sensitive to such ionic gate, which was attached from the top of the OFET channel. Also, as mentioned above, already the ionic liquids are used to tune the electrical conductivity of the interfacial region of different materials, ranging from semiconductors to even superconductors [17-21], but this was not used in any types of monolithic devices with inventive architectures, distinct from two-electrode capacitor type device for EDLC

Although there has been some work done [16] in the area of ionic liquids in organic photodetectors of OPV type, these systems are two-electrode systems and require a pulsed light illumination to get some useful photoresponse. It operates due to displacement current, while a transport current is not possible in those devices with capacitive coupling of electrodes in ionic component.

### SUMMARY OF THE INVENTION

The claimed invention is directed to a novel type of monolithic hybrid technology. The invention is directed to photonic devices with a minimum of three (3) electrodes and by an inventive process for incorporating mobile ions into organic components of high performance organic photovoltaic (OPV) devices, organic photodetectors and other hybrid photonic devices (such as tandems of OPV), through a novel unique device architecture of a hybrid “Ionic-NT-OPV” structure, in which the ionic components are separated from the OPV by a common nanoporous charge collecting electrode (symbolically depicted for simplicity as a nanotube: NT), permeable to ions of ionic liquid inside an inter-connected microchamber.

Embodiments of the present invention are directed to a novel type of a monolithic device that uses a process for incorporating mobile ions (such as ions in ionic liquids) into high performance OPV films through a novel unique device architecture of a hybrid “Ionic-NT-OPV” structure, in which the ionic components are separated from the solid OPV parts by a nanoporous charge collecting common electrode, highly permeable to ions within an inter-connected microchamber. This three electrode structure can be distinguished from the two-electrode structure described by Li et al [16].

In certain embodiments of the invention, the nanoporous common electrode is a carbon nanotube (CNT) transparent sheet electrode. The microchamber forms an ionic reservoir, from which ions can penetrate into the OPV part of a hybrid via highly porous nanostructured electrode. As the ions pass through the CNT electrode (which has electronic charge provided either by photogeneration in OPV part, or by voltage applied to a gate counterelectode of ionic part) and into the active layers of the OPV, the electronic charges in both the upper layers of polymer and in the CNT-common electrode themselves are stabilized by double layer charging effects by ions, resulting in effective doping. This effect can be viewed as tuning of OPV parameters by doping via ionic components, and such hybrid ionic-CNT-OPV device can be thus reconfigured by ionic EDLC charging of a common electrode and adjacent to it organic layers.

It should be mentioned that using CNT electrodes, which can be tuned by EDLC by ionic component as part of an inorganic Shottky barier type Si-solar cell has been described in US Published Application No. US2012031237. However, in this reference, the tuning of CNT changes the nature of the barrier between CNT and the doped Si crystal, turning it from ohmic into a Scottky barrier, which thus creates a built-in potential, needed for separation of photogenerated carriers in Si semiconductor. The present invention differs from the described prior art in at least two important respects: 1) First, in the prior art cells, only the CNT electrode is doped, which changes its barrier property; whereas in the present invention, the CNT are doped first by EDLC and then the doping propagates inside the organic material, also doping electronically (either by EDLC or by Faradaic electrochemical process), the layers of organic material adjacent to the CNT, e.g. chains of conjugated polymer. This process creates an ohmic contact between negatively charged n-type CNT and a similarly n-doped polymer layer of OPV, which is quite opposite to formation of Schottky barrier as set forth in the prior art; 2) Second, the CNT electrode in Si-solar cell case is not highly porous in the part that is connected to Si and does not penetrate as a 3-D network into the bulk of the semiconductor matter; whereas in the present invention the 3-D network of porous NT inside the organic layer creates an extended ohmic contact between a CNT cathode and doped organic (photoactive or transport) layer, which allows an improvement in the collection of charges, while charges are photogenerated in the photoactive layers of OPV, not influenced by EDLC doping. Although the EDLC doping of CNT is present in both the prior art invention and the claimed present invention, in the case of the present invention, the ions partially penetrate into organic layers, improving their properties in OPV, as can be seen from the improved fill-factor relative to the cells in the prior art.

An embodiment of the invention is directed to the design and development of a hybrid “Ionic-NT-OPV” device, in which the high porosity and huge interface of transparent NT nanoporous electrodes allow quick redistribution of ions on the surface of electronically charged NTs, (either upon applied voltage bias to ionic part or upon photoexcitation of OPV part) leading to the electronic doping of porous NT network electrode and adjacent organic layers and the formation of ohmic contacts between NT with this adjacent organic layers. Moreover p-type or n-type ionic EDLC induced electronic doping of the adjacent organic layers will also create p-I and n-I junctions with undoped parts of same organic layers inside the OPV (or other organic photonic device: OPD) that are favorable for charge separation and collection.

Embodiments of the invention are directed to a hybrid monolithic structure comprising an ionic liquid electrolyte sealed in a micro-chamber and an OPV solid portion, which are separated by a common electrode comprised of a nanotube NT or any other highly porous, nanostructured conductive network, such as nanoribbons, or nanoflakes and other structures with open porosity networks.

### BRIEF DESCRIPTION OF THE DRAWINGS

FIG. 1 shows a highly simplified schematic of the proposed device structure, showing the device as two components, the ionic component, which is a liquid or soft material and the photovoltaic component, which is a solid material. Both components share a common NT electrode with open porosity. The structure is then sealed between two substrate structures, which are typically glass coated with a transparent conducting oxide layer.

FIGS. 2(a) to 2(d) show ELDC charging mechanisms and ion motion within the devices in accordance with embodiments of the invention, for both bilayer OPV devices and bulk heterojunction geometry of OPV devices.

FIG. 3a shows a typical structure for an organic solar cell using small molecules materials that are usually deposited with vacuum processes, in which the charging common electrode is planar with respect to the OPV. FIG. 3b shows the structure with specific examples of materials used on a small molecule solar cell.

FIG. 4a shows a typical structure for an organic solar cell using small molecules materials that are usually deposited with vacuum processes, in which the charging electrode is monolithically aligned to the OPV. FIG. 4b shows the structure with specific examples of materials used on a small molecule solar cell.

FIG. 5 shows experimental results using a device prototype based on the design described in FIG. 2d. OPV were fabricated in an inverted configuration with a ZnO coated-ITO bottom cathode and semi-transparent multiwall nanotube MWCNT top anode. The test devices had a photo-active layer formed from a bulk hetero-junction of P3HT and PCBM.

FIG. 6 shows examples of the types of ionic liquids which can be used as ionic components in the hybrid devices of the claimed invention.

FIG. 7 shows the cross-section of the ionically-gated organic photovoltaic device in the so-called “regular structure” configuration.

FIG. 8 shows a generalized device structure of an inverted structured device. The inset depicts layers that may be used in this device structure but typical devices may only utilize one of the layers. Voltage may be applied (14) to a gate in order to charge electrodes (5) and (7). Positive voltages will charge electrode (5) resulting in n-type doping and negative voltages will charge electrode (5) by p-type doping.

FIG. 9 shows a 3-dimensional representation of the device in accordance with an embodiment of the invention demonstrating how the gate electrode is horizontally separated from the common porous electrode. The solar radiation source (16) indicates that the cell is illuminated from the bottom side. For the described examples, the light is typically the AM1.5G spectrum which is a close match in spectral makeup and intensity to natural sunlight at sea level and near the equator.

FIGS. 10(a) to (d) show SEM images of a variety of carbon nanotubes with different porosity and different size of bundles—(a) is a sample of MWCNT bucky paper with small bundle sizes; (b) is a sample of Nanoesko SWCNT with small bundles; (c) is a sample of MWCNT with large bundle size and (d) is a sample of SWNCT from Nanocomp with larger bundle sizes.

FIG. 11 shows a rough schematic of the density of electronic states (DOS) of a semiconducting single walled carbon nanotube contrasted with the energy levels of the OPV device in the Voc regime. The black areas indicate states filled by electrons and the light gray indicates empty states. FIG. 11(a) depicts the intrinsic p doped state and FIG. 11(b) depicts the positively charged, n-doped state and shows that the organic acceptor layers adjacent to the CNT are also doped creating an i-n built in potential in the organic layers as well as ohmic contact between the CNT and organic layer. This improves the filling factor of the OPV device.

FIG. 12(a) shows a bulk surface which has low surface area exposed to an ionic liquid. FIG. 12(b) depicts a porous surface with approximately seven times the surface area of (a). FIG. 12(c) depicts a porous surface which is capped with an impermeable material closing off all of its surface.

FIG. 13 shows the energy levels of undoped (a) and doped (b) states; and

FIG. 14 shows the results of testing a regular structured hybrid “ionic-OPV” device similar to the structure shown in FIG. 7. FIG. 14(a) depicts the IV curves as a function of differing gate voltage and FIG. 14(b) shows the parameters derived from the curves.

### DETAILED DESCRIPTION OF EXEMPLARY EMBODIMENTS

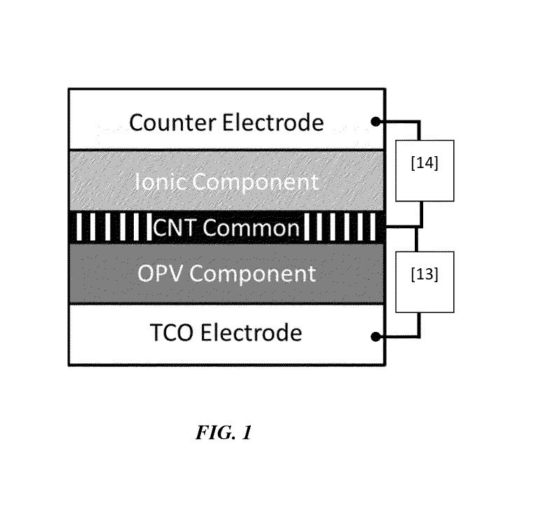

The present invention is directed to a monolithic three electrode device that can be viewed as a device composed of two functionally and structurally different components—the solid state organic device component and the ionic liquid component, separated by a common tunable electrode that is highly porous, has open porosity and large interface area, and is sensitive to EDLC charging by ionic component. This common electrode, exemplified by CNT network is not only ion-permeable, but its electronic properties are highly tunable by charge injection, due to very low density of electronic states (DOS), which have Van-Hove singularities due to 1-dimensional geometry. Similarly a 2-D common electrode based on graphene nanoribbons GRN network or graphene oxide based porous media, also can be used as another good candidate for tunable common electrode due to low DOS and large interface and large initial mobility of charges. The ionic part of a monolithic device comprises a micro-chamber between the common electrode and second cover glass (with typical thickness in the micron scale). It has mobile ions forming a battery or a supercapacitor part due to a presence of a counterelectrode, serving as a gate or third electrode in the hybrid device (as shown at FIG. 1).

Due to this supercapacitor/ionic mini-reservoir, the operation of this two component device differs significantly from any conventional organic PV or photodetector device. Charging with an applied bias to gate electrode on the supercapacitor ionic part, moves negative ions to the gate and the same amount of positive ions into the pores of a tunable CNT common electrode of the OPV component. This forms a negative EDLC charging in the tunable CNT bundles and thus causes doping of the CNT common electrode by n-type via ionic penetration on the outer interface of CNT bundles. The same positive ions also spread partially into the adjacent to CNT organic layers resulting in favorable n-type doping of the organic layers (e.g. transport layer), thereby improving its electronic conductivity and forming an ohmic contact with the CNT common electrode.

During ionic gating, the EDLC charging of the supercapacitor ionic part under bias injects a large electronic charge into CNTs, due to the giant capacitance of CNT arising from its huge interface area. The injected into CNT electronic charge significantly shifts the Fermi level of CNT and hence the effective work function. This strong effect of filling of the CNT bands with either electrons or holes has been independently proven in the separate EDLC charging of CNT [31] observed as work function modulation.

It has been shown that negative voltage at the CNT common electrode from the counter electrode results in electron accumulation and decreases the common CNT electrode work function, and changes the cold emission properties of cathodes in vacuum. In the present invention this physical process is used in the monolithic device for changing the nature of the CNT electrode and reconfiguring it into a transparent cathode from the initial anode.

There are several different methods set forth in the instant application for connecting the ionic microchamber and OPV components. The general structure of the inventive device is one in which the OPV is fabricated on top of glass that is coated with a transparent conductive oxide (TCO/bottom seal), following which the ionic component is fabricated on top of the OPV layer. A common CNT layer, serving as a common electrode is sandwiched between the OPV component and the ionic component. Following the fabrication of the ionic component, a glass layer coated with another TCO serving as a counter-electrode is placed atop the liquid ionic component to form a top seal. The polymeric insulating gasket (not shown here for simplicity) provides a side seal of the two connected chambers, keeping ionic liquid inside the structure and avoiding leakage out of it. FIG. 1 depicts a generalized device structure in accordance with an embodiment of the invention. Junction 13 is where the electrical properties of the solar cell such as open-circuit voltage and short-circuit current are measured. Junction 14 is where the gate bias to the counter electrode is applied.

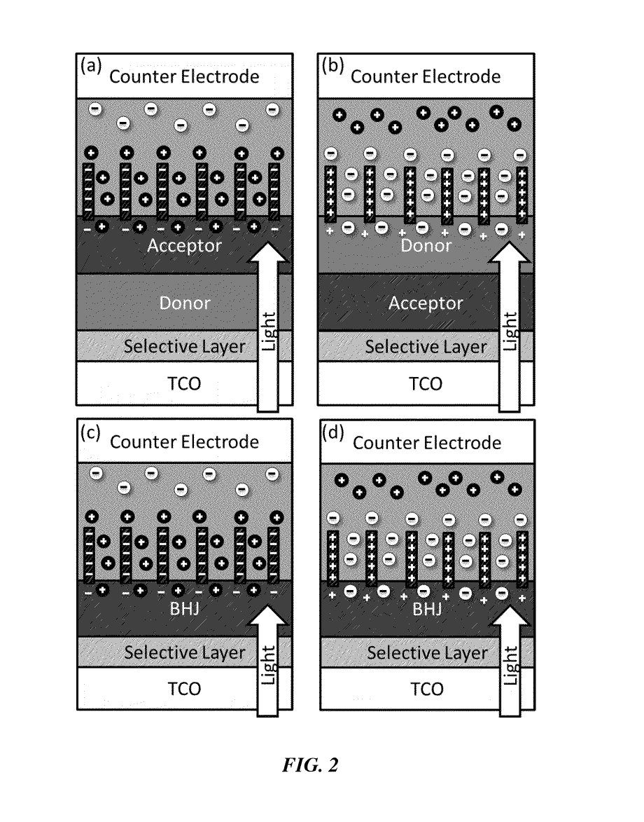

Another embodiment of the invention is directed to a bilayer structure OPV where the acceptor layer is on top of the donor layer as shown in FIG. 2a. In other words, the charge selective layer blocks electrons but allows for the passage of holes. This makes the TCO electrode the anode, and the CNT electrode, becomes the common cathode. In this example, no bias is applied to the counter electrode of ionic chamber. Upon photoexcitation, the acceptor layer of OPV (such as fullerene C60 or PCBM) and the carbon nanotubes common electrode become negatively electronically charged and attract positive ions from the ionic liquid, in such a way, that plus ions penetrate through open pores of NT into upper layers of OPV. This results in n-type doping of the carbon nanotubes and the adjacent acceptor and creates and improves the ohmic type electrical contact between these two layers. This is indeed observed experimentally in improved filling factor (FF) and improved photocurrent, (i.e. short circuit current, Isc) extraction from the device.

A further embodiment of the invention is directed to a similar, (but inverted as compared to described above) bilayer structure OPV with the donor layer (such as PHT: poly[hexylthiophene] conjugated polymer) on top of the acceptor layer as shown in FIG. 2b. The charge selective layer (such as ZnO) blocks holes but allows for the passage of only electrons. This makes the bottom TCO electrode the cathode and the CNT common electrode, thus is serving now as the common anode. In this example, no bias is applied to the counter electrode of the ionic chamber. Upon photo excitation, the donor layer and the carbon nanotubes become positively electronically charged and attract negative ions from the ionic liquid part. This results in p-type doping of the carbon nanotubes and the donor layer adjacent to NT and enhanced ohmic contact between these two layers. This is observed in improved filling factor and improved photocurrent extraction from the device increasing the overall power efficiency of OPV.

Another embodiment of the invention is directed to a BHJ structure OPV where the charge selective layer (such as PEDOT-PSS or MoO₃) blocks electrons but allows for the passage of holes. This makes the bottom TCO electrode the anode and the common CNT electrode becomes the cathode of a hybrid. In this example, again no bias is applied to the counter electrode of ionic chamber. This is described by FIG. 2c. Upon photo excitation, the acceptor material in the BHJ and the carbon nanotubes become negatively charged and attract positive ions from the ionic liquid into the pores of CNT. This results in n-type doping of the carbon nanotubes and the acceptor layer adjacent to NT and creates and improves the ohmic contact between these two layers. This is observed in improved filling factor and improved photocurrent extraction from the device, increasing the overall power efficiency of OPV.

A further embodiment of the invention is directed to a bulk heterojunction (BHJ) structure OPV in an ‘inverted structure’. Here, the charge selective layer blocks holes but allows for the passage of electrons. This makes the bottom TCO electrode cathode and the middle CNT electrode becomes the common anode. In this example, no bias is applied to the counter electrode of ionic chamber. This is described by FIG. 2d. Upon photo excitation, the donor material in the BHJ and the carbon nanotubes become positively charged and attract negative ions from the ionic liquid. This results in p-type doping of the carbon nanotubes and the donor layer adjacent to NT and enhanced ohmic contact between the two layers. This is observed in improved filling factor and improved current extraction from the device.

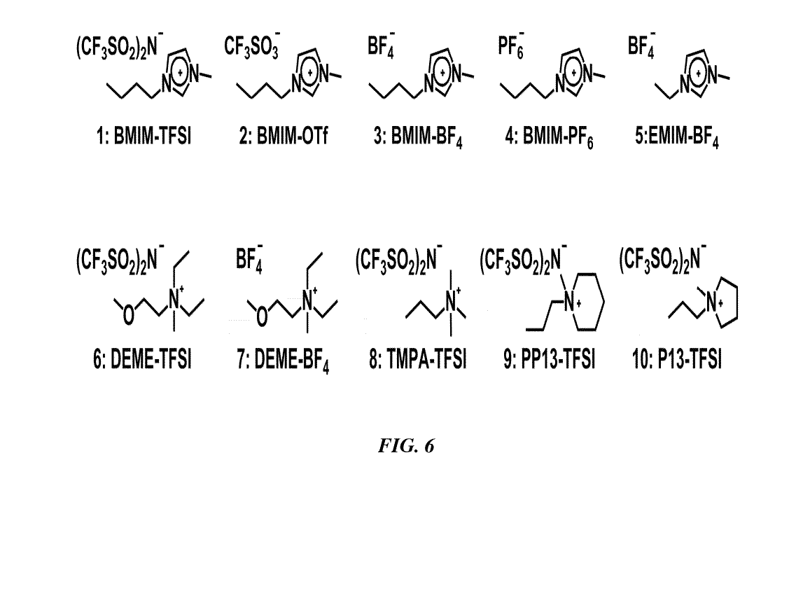

A further embodiment of the invention is directed to above mentioned BHJ type OPV of either a direct type (or inverted type) both described above, when the bias is applied between the counter-electrode of the ionic chamber and common CNT porous electrode. This bias should be adjusted to such value that is higher than the difference between the electrochemical potential of ionic liquid and the Fermi level in CNT, but lower than the difference of electrochemical potential of ionic liquid and the corresponding HOMO of donor (or LUMO of acceptor in inverted BHJ device case). In this case the charges (electrons or holes respectively) will be injected into CNT common electrode, and this charging will attract ions into pores of CNT creating double layer stabilization of charges, and thus doping of CNT only. At high enough doping level some of adjacent layers of donor (or acceptor) also will be doped. One should avoid applying higher counter electrode gate bias, since in this case the donor (or acceptor) layers will be completely charged, decreasing the photogeneration of excitons and thus decreasing photogeneration of charges. Then counter electrode bias can be switched off, just before applying the photoexcitation (e.g. by solar light). The double layer in highly nanoporous materials like CNT with huge interface is known to be stable for reasonable time even when the counter electrode bias is removed [31], therefore the doped CNT and slightly doped organic layers will provide enhanced photocurrent and improved FF and thus enhanced power efficiency in OPV part, as in described above examples with photocharging only. This type of pre-charging of OPV by a properly chosen counter electrode bias in ionic chamber needs careful adjustment of counter electrode bias for each type of ionic liquid, shown in FIG. 6, depending on electrochemical potential of certain ionic liquids used, relative to HOMO of a donor (or relative to LUMO of an acceptor) layers.

Both cases of pre-charging are described below as separate examples for direct and inverted BHJ OPV, with emphasis on doping levels, achieved by counter electrode biases compared to photocharging.

Another embodiment of the invention utilizes the same structure as FIGS. 2a and 2b. However, here counter electrode gate bias is applied between the counter electrode and the CNT common electrode. This is technically similar to FIG. 2a or FIG. 2b depending on the counter electrode bias level applied and choice of selective layer and ionic liquid; however, the degree of doping is higher in this case as compared to photodoping. The higher level of doping produces higher electrical conductivity of the carbon nanotubes and enhanced photogenerated charge extraction. This is seen in higher filling factors and currents as well as higher open circuit voltages. A first example is a regular configuration with hole selective (electron blocking) layer and positive gate bias applied to the counter electrode. This is depicted in FIG. 2a. A second example is an inverse configuration with electron selective (hole blocking) layer and negative gate bias applied to the counter electrode. This is depicted in FIG. 2b.

A further embodiment of the invention utilizes the same structure as FIGS. 2c and 2d. But now an electrical bias is applied between the counter electrode and the CNT common electrode. This is technically similar to FIG. 2c or FIG. 2d depending on the bias applied and choice of selective layer; however, the degree of doping is higher in this case. The higher level of doping produces higher electrical conductivity of the carbon nanotubes and enhanced charge extraction. This is seen in higher filling factors and currents as well as higher open circuit voltages. A first example is a regular configuration with hole selective (electron blocking) layer and positive bias applied to the counter electrode. This is depicted in FIG. 2c. A second example is an inverse configuration with electron selective (hole blocking) layer and negative bias applied to the counter electrode. This is depicted in FIG. 2d.

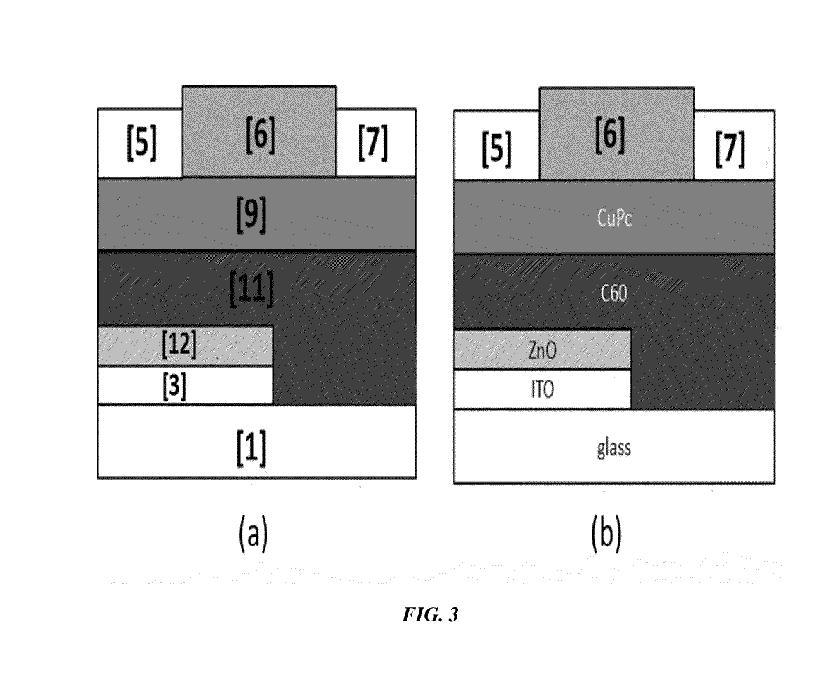

The concept of the ionic doping of solar cells is not limited to only solution processed active layers. FIG. 3a illustrates a solar cell with the use of small molecules materials that are usually deposited with vacuum processes, in which the charging electrode is planar with respect to the OPV. A TCO layer is deposited and patterned on a substrate and is used as the bottom electrode of the cell. Next, a selective layer is utilized prior to the deposition of the active layers. The selective layer modifies the work function to TCO and may also acts as a charge blocking layer. The active layer consists of an electron donor material and an electron acceptor material. The material layers are either deposited on top of each other to form a bilayer junction or are co-deposited at the same time to form a bulk heterojunction. The top electrode is fabricated by transferring freestanding CNT sheets of the top of the active layer. An additional counter electrode is fabricated by an additional CNT sheet next to top electrode. A droplet of ionic liquid is dropped on top, so that it covers device and extends across the top electrode, the active layer and the counter electrode.

Indium Tin Oxide (ITO) is the most common TCO used, but other materials such as CNT and graphene may be deposited and substituted for conventional ITO. As shown in FIG. 3b, a layer of zinc oxide (ZnO) is deposited on ITO to facilitate electron extraction from fullerene (C60). Other commonly used layers are titanium oxide (TiOx) and PFN ceramics. The active layer consists of acceptor layer C60 and donor layer copper phthalocyanine (CuPc) (other donor materials include zinc phthalocyanine (ZnPc)). Prior to the transfer of CNT sheets on the top, a charge transport layer may be applied. Transport layers can be materials such as TPD, MeoTPD, mTDATA, NPB. Dopants can also be used to improve performance of transport or donor-acceptor layers (such as p-type F4TCNQ). In case of n-type doping, materials such as Li, Cs, AOB, PyB are commonly used. The top electrode (a common tunable electrode) is fabricated by transferring freestanding CNT sheets of the top of the active layer. An additional counter electrode (gate electrode) is fabricated by an additional CNT sheet next to top electrode. Finally, a droplet of ionic liquid is drop casted on the surface of the CNT of the OPV sub-cells.

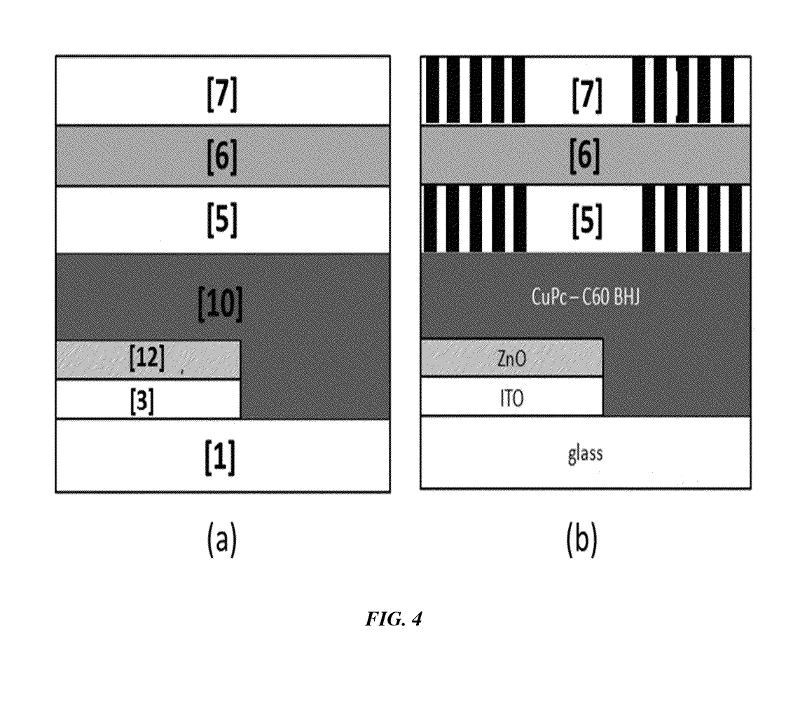

FIG. 4a illustrates an organic solar cell using small molecules materials that are usually deposited with vacuum processes, with the charging cathode monolithically aligned with respect to the OPV. A TCO layer is deposited and patterned on a substrate and is used as the bottom electrode of the cell. Next, a selective layer is utilized prior to the deposition of the active layers. The selective layer modifies the work function to TCO and may also acts as a charge blocking layer. The active layer is consisted by an electron donor material and an electron acceptor material. The material layers are either deposited on top of each other to form a bilayer junction or are co-deposited at the same time to form a bulk heterojunction. The top electrode is fabricated by transferring freestanding CNT sheets of the top of the active layer. A gasket of Surilyn between OPV and cover glass plate is placed to contain the ionic liquid on the surface area. The counter electrode deposited on cover glass plate.

FIG. 4b illustrates an example of such a device. ITO is the most common TCO used but other materials as CNT and graphene may be deposited and substitute conventional ITO. A layer of ZnO is deposited on ITO to facilitate electron extraction from C60. Other commonly used layers are TiOx and PFN. Active layer consists of acceptor layer C60 and donor layer CuPc (or others donor materials such as ZnPc). Prior to transfer of CNT sheets on the top, a charge transport layer may be applied. Transport layers can be materials such as TPD, MeoTPD, mTDATA, NPB. Dopants can also be used to improve performance of transport or donor-acceptor layers (such as p-type F4TCNQ). In case, of n-type doping of materials such as Li, Cs, AOB, PyB are commonly found. The Surilyn gasket is placed and a cover plate with counter electrode is placed to finalize the cell structure. The droplet of ionic liquid is drop casted on the surface of the cells and then closed with cover plate or it is inserted through an opening at the cover plate.

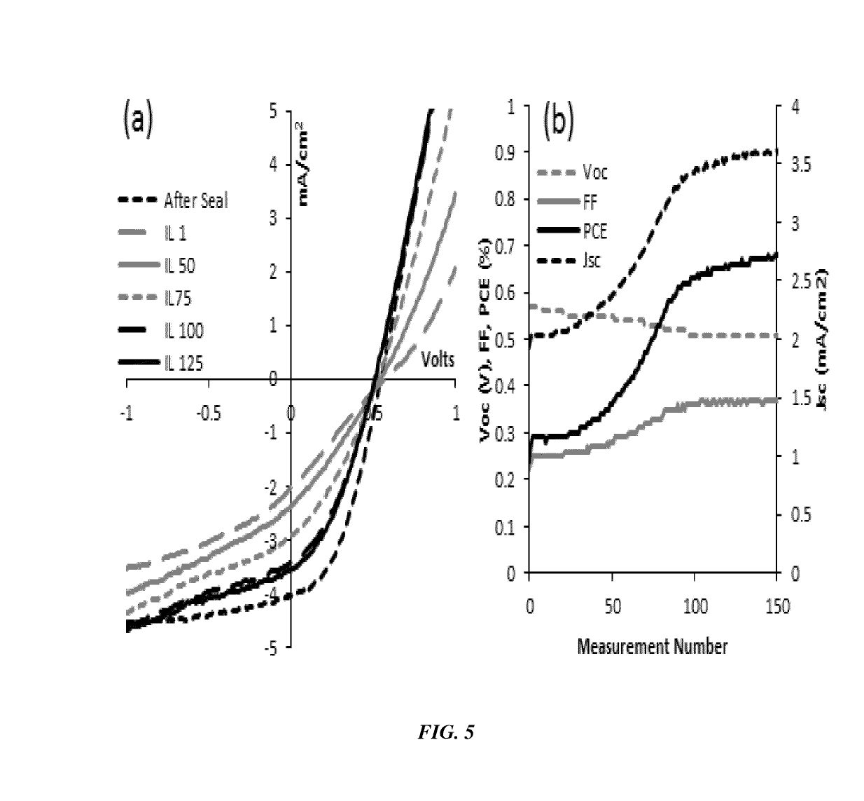

FIG. 5 depicts experimental results using a device prototype based on the design described in FIG. 2d. OPV were fabricated in an inverted configuration with a ZnO-ITO bottom cathode and semi-transparent MWCNT top anode. The test devices had a photo-active layer formed from a bulk hetero-junction of P3HT and PCBM.

FIG. 6 depicts the types of ionic liquids, which can be used in the hybrid devices of the claimed invention. The liquids are BMIM, 1-butyl-3-methylimidazolium; EMIM, 1-ethyl-3-methylimidazolium; DEME, N,N-diethyl-N-methyl(2-methoxyethyl)ammonium; TMPA, N,N,N-trimethyl-Npropylammonium; PP13, N-methyl-N-propylpiperidinium; P13, N-methyl-N-propylpyrrolidinium; TFSI, bis(trifluoromethylsulfonyl)imide; OTf, trifluoromethanesulfonate; BF4, tetrafluoroborate; and PF6, hexafluorophosphate.

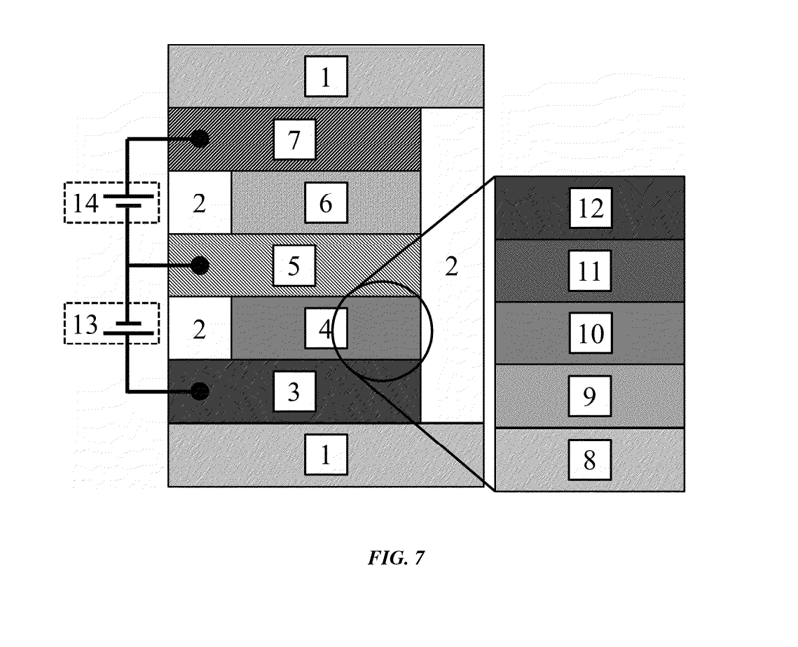

The following is the description of a preferred embodiment of the present invention, in which the ionically-gated organic photovoltaic monolithic structure is therein described. FIG. 7 shows the cross-section of the ionically-gated organic photovoltaic device in the so-called “regular structure” configuration. The device comprises inert, transparent backing layers 1, which enclose the rest of the components, optional encapsulating seals 2, a highly-conductive transparent anode 3, the photoactive organic-composite layer 4, a highly-conductive, porous and transparent charging electrode 5, the electrolyte component 6, and the counter electrode 7. For the “regular structure”, the photoactive organic-composite layer 4 is described in detail, consisting of—the hole transport/electron blocking semiconductor layer 8, an optional electron-donating semiconductor layer 9, a bulk-heterojunction or homogenous layer consisting of a blend of electron-donating and electron-accepting semiconductors, or an ambipolar semiconductor, an optional electron-accepting semiconductor layer 11, and an optional electron transport/hole blocking semiconductor layer 12. Layers 5 and 7 are capacitively charged via a power source 14 and photovoltaic power is extracted via the outlet 13.

The electron-donating semiconductors in layer 4 are p-type materials and may comprise a single or a combination of several semiconductor materials. The electron-accepting semiconductors in layer 4 are n-type materials and may comprise a single or a combination of several semiconductor materials. Furthermore, the semiconductor materials may be organic, metal-organic, or organic-composite, and the semiconductors may comprise small molecules, oligomers, or polymers.

The p-type organic semiconductor materials will comprise of small molecules such as pentacene, phthalocyanine, tetrabenzoporphyrine, or (biphenyl)tetrathiafulvalene. Alternatively, the p-type organic semiconductor material may be an oligomer such as di-hexyl quaterthiophene, alpha-sexithiophene, a thiophene-phenylene oligomer, or a thiophene-thiazole oligomer. Also, the p-type organic semiconductor material may be a polymer such as poly[3-hexylthiophene] (P3HT), poly[5,5′-bis(3-dodecyl-2-thienyl)-2,2′-bithiophene] (PQT-12), poly[9,9-dioctylfluorene-co-bithiophene] (ADS2008), or poly[2-methoxy-5-(2′-ethylhexyloxy)]-1,4-(1-vinylene)phenylene] (MEH-PPV). Other possible p-type semiconductor materials include metal-organic complexes such as Cu-phthalocyanine, Mg-phthalocyanine, or Zn-phthalocyanine and methyl ammonium lead iodide (CH₃NH₃)PbI₃. Furthermore, such metal organic complexes may be oligomeric, as in Si-phthalocyanine or Ru-phthalocyanine, or even polymeric.

The n-type organic semiconductor materials will comprise of small molecules such as perylenetetracarboxylicacid dianhydride (PTCDA), 2,3,5,6-Tetrafluoro-7,7,8,8-tetracyanoquinodimethane (F4-TCNQ), dimethylperylenetetracarboxylicacid diimide (MePTCDI), fullerene (C₆₀), C60-fused pyrrolidine-metaC12 phenyl (C₆₀MC₁₂), or [6,6]-phenyl C₆₁-butyric acid methyl ester (PCBM). The n-type organic semiconductor material may also be oligomeric comprising thiazole oligomers with 4-trifuormethylphenyl groups, thiazole/thiophene co-oligomers with 4-trifluormethylphenyl groups, perfluoroarene-capped oligothiophenes such as 5,5″-diperfluorophenyl-2,2′:5′,2″:5″,2′″-quaterthiophene, or perfluorinated phenylene dendrimers such as C₆₀F₄₂ or C₁₃₂F₉₀. Also, then-type organic semiconductor material may be a polymer such as polybenzaimidazobenzophenanthroline (BBL or poly[2-methoxy-5-(2′-ethylhexyloxy)-1,4-(1-cyanovinylene)phenylene] (MEH-CN-PPV). Other possible n-type semiconductor materials include metal-organic complexes such as perfluorovanadyl-phthalocyanine, perfluoro-copper-phthalocyanine, tetrapyridotetraaZaporphyrinato Zinc(II) (TPyTAPZn), tris(8-quinolinolato)aluminium (Alq3), tris (4-methyl-8-quinolinolato)aluminium (Almq3), bis(10-hydroxybenZo[h]-quinolinato)beryllium (BeBqZ), bis(2-methyl-8-quinolinolato)-(4hydroxy-biphenylyl)-aluminium (BAlq), bis[2-(2hydroxypheyl)-benZoxaZolato]Zinc (Zn(BOX)2), or bis[2-(2hydroxypheyl)-benZothiaZolato]Zinc (Zn(BTZ)₂).

The charging 5 and counter 7 electrode consists of a highly porous network is formed of at least one member selected from a group of one-dimensional or two-dimensional materials. The one-dimensional materials used can consist of, but not exclude, metal/semiconductor nanotubes, nanowires, nanorods and intrinsically 1D materials. Metals used can be, but not excluding, Sc, Y, Ti, Zr, Hf, Rf, V, Nb, Ta, Db, Cr, Mo, W, Sg, M, Tc, Re, Bg, Fe, Ru, Os, Hs, Co, Rh, Ir, Mt, Ni, Pd, Pt, Ds, Cu, Ag, Au, Rg, Zn, Cd, Hg, Cn. Semiconductors used can be, but not excluding Si, Ge, Sn, MoS₂, CdS, CdSe, PbTe. Intrinsically 1D materials include, charge-transfer salts (TTF-TCNQ BETFF for example), Two-dimensional materials include graphene, silacene, germanane, boron nitride, tungsten oxide or chalcogenides (WX₃), molybdenum dioxide or dichalcogenides (MoX₂), molybdenum oxide or chalcogenides (MoX₂) niobium dioxide or dichalcogenides (NbX₂), tantalum dioxide or dichalcogenides (TaX₂), manganese dioxide or dichalcogenides (MnX₂) and organic charge transfer salts such as κ-(ET)₂Cu[N(CN)₂]Cl.

For the electrolyte 6, materials used can include solvent-electrolytes, ionic liquids (such as EMIM-FS, EMIM-BETI, DEME-TFSI, MMIM-TFSI, EMMIM-TFSI, BMIM-TFSI, BMIM-BF₄, BMIM-OTf, BMIM-PF₆) and polymer/solid electrolytes (such as polyethylene-oxide (PEO)).

The substrate 1 may be glass, a rigid or flexible polymer, e.g., a screen protector or skin, or may be combined with other layers such as encapsulating layers, anti-reflecting layers or the like. The transparent anode 3 can be formed of conducting oxide, e.g. ITO and or MoO₃. It should be understood that 3 may be formed of other materials such as tin oxides, fluorinated tin oxides, nanotubes, Poly(3,4-ethylenedioxythiophene) (PDOT) or PEDOT:PSS (Poly(3,4-ethylenedioxythiophene)poly(styrenesulfonate)), gallium doped zinc oxide, aluminum doped zinc oxide and other materials having suitable transparency and conductivity. The optional encapsulating seal 2, can be of polymeric origin, such as surlyn, epoxy or silicone, but also be inorganic, such as moldable glass.

After initially measuring the solar cell parameters, the OPV devices were sealed by second glass plate, using a thin 50 μm gasket of Surilyn between OPV and cover glass plate. The glass plate has a hole drilled in it preceding sealing to allow filling with the ionic component. Tests have indicated that this sealing method does no harm to the solar cell even if the gasket is placed directly on the active area. The micro-cavity reservoir was then filled with ionic liquid by placing the device in a desiccator under light vacuum. As the air is removed from the micro-cavity, the ionic liquid placed in the hole can flow in filling the empty volume. The hole can then be sealed by thin glass, completing the device.

Solar cells were exposed to light from an AM1.5G solar simulator calibrated to one sun (100 mW/cm²). It was that the solar cells parameters improved purely by light illumination without any bias applied to the counter electrode (or the counter electrode and anode shorted).

Inventive devices of the claimed invention are based on combining ionic components with a solid state (polymeric or small molecule organic photosensitive) layer, connected to each other via optically transparent layers that are highly permeable to ions. The device can be generally viewed as a two component device: one component being a chamber with ions forming a battery or a supercapacitor, while the other component is an OPV.

With the supercapacitor/ionic-reservoir involved, the operation of this hybrid tandem device differs significantly from conventional OPVs; charge carriers which are photogenerated in the photoactive layers of the OPV part of the hybrid move to the CNT anode and the transparent conducting oxide (TCO) cathode, creating a photovoltage (V_{OC}). The charging of the CNT electrode due to this V_{OC} photovoltage attracts ions in the chamber from the ionic liquid, forming a charged double-layer (DLC) on CNT bundles and thereby doping the CNT electrode with photogenerated carriers which are stabilized by ionic component. The ions can also spread partially into the upper layers of the OPV adjacent to CNT, resulting in favorable doping of the photoactive layers improving electronic conductivity. The doping level of the CNT electrode and OPV layer will increase with exposure to light, increasing the conductivity of the charge transport layers and resulting in increased short-circuit current (ISC) and fill-factor (FF) of the OPV. This effect has been observed in preliminary experiments, conducted in conventional PHT/PCBM OPV with various ionic liquids.

The description of the components in FIGS. 7-9 is set forth below:

1. Substrate & Cover—These may be glass, silicon or plastic, and need not be the same material.

2. Seal—This may be an epoxy or heat sealable polymer which serves to contain the electrolyte in the reservoir and prevent air from reaching the device.

3. Device Electrode—This electrode may be a transparent conducting oxide such as ITO or FTO, a metal such as gold, or other conductive materials such as CNT, PEDOT:PSS, or Graphene.

4. Device Semiconducting Layers—These layers make up the active layers of the device. These may be organic or inorganic semiconductors or some combination of each. The inset shows that this generally includes several nanoscale layers which are described in components 8-12.

5. Porous Common Electrode—This electrode is characterized by a low, but non-zero, density of states at the Fermi level, a very large surface area to volume ratio and nanoscale porosity. As this layer is charged along with the adjacent semiconducting layers, the device functionality is modified.

6. Electrolyte—This may be an ionic liquid, a salt in organic solvent, a solid-state electrolyte, or a gel electrolyte. This medium serves to charge electrode (5) when a bias is applied between it and electrode (7).

7. Gate or Counter Electrode—This may be a material similar to electrode (5), but could also be a platinum or other metal mesh or wire.

8. Hole Transport Layer—A hole transport layer such as PEDOT:PSS transports holes while blocking electrons or excitons. This create a selective electrode, but can also reduce hole injection barriers between the anode and the semiconductor layer.

9. Donor—This layer is made up of an electron donor material which could be organic or inorganic materials. In the case of organics, this will typically be a conjugated polymer, or dye molecule. In the case of doped semiconductors, this material is a p-type semiconductor.

10. Bulk Heterojunction of Donor and Acceptor—This layer is made of a mix of donor (8) and acceptor (11) materials which forms interconnected nanoscale pathways through the layer. The donor-acceptor heterojunction is responsible for the efficient separation of excitons into free charge carriers.

11. Acceptor—This layer is made of an electron acceptor material which could be an organic material such as a fullerene or an inorganic material such as titanium oxide nanoparticles. In the case of doped semiconductors, this material is a n-type semiconductor.

12. Electron Transport Layer—A hole transport layer such as zinc oxide transports electrons while blocking holes or excitons. This create a selective electrode, but can also reduce electron injection barriers between the anode and the semiconductor layer.

13. Device Voltage—This is a voltage applied or generated between electrodes (3) and (5). This is the device's output.

14. Charging Voltage—This is a voltage applied or generated between electrodes (5) and (7). This is the supercapacitor's output.

15. Capping Layer—This capping layer could be any non-permeable material.

### WORKING EXAMPLES

### Example 1

### Regular Structured Device

FIG. 7 shows a generalized device structure having a regular structure. The inset depicts all of the layers that may be used in this device structure. However, typical devices may only utilize one of the depicted layers 8 through 12. Voltage (14) may be applied to charge electrodes (5) and (7). Positive voltages will charge electrode (5) n-type and negative voltages will charge electrode (5) p-type.

In an embodiment of the invention, Poly(3,4-ethylenedioxythiophene):poly-(styrenesulfonate) PEDOT:PSS from Heraeus (Clevios™ PVP AI 4083) was filtered through a 0.45 micron nylon filter and spin-coated onto UV-ozone treated, patterned ITO-glass substrates, resulting in a 30 nm thick layer. The substrates were annealed at 180° C. for five minutes. A 1:1 solution of poly(3-hexylthiophene-2,5-diyl) (P3HT: P200, Rieke Metals Inc.) and phenyl-C61-butyric acid methyl ester (PCBM: Nano-C) in chlorobenzene was then spun onto the PEDOT:PSS substrate, allowed to rest overnight and then annealed at 170° C. for five minutes. The total device thickness was measured to be 200 nm thick by a stylus profilometer.

Highly oriented CNT sheets approximately 3 mm wide were dry-pulled from a CNT forest synthesized at UTD, and laid on top of the P3HT:PCBM layer. After five layers were laid, the carbon nanotubes were densified with 3M™ Novec™ 7100 Engineered Fluid, methoxy-nonafluorobutane (C4F9OCH3). An additional five layers were applied to the bare glass and ITO on the far side of the device to serve as a gate electrode. Contacts were created using silver paint. A drop (˜10 ul) of ionic liquid, N,N-Diethle-N-methyl-N-(2-methoxyethyl)ammonium tetrafluoroborate, DEME-BF4 (Kanto Chemical Co. Inc.), was placed on top of both CNT electrodes. A glass microscope cover-slip was placed on the ionic liquid to spread and contain it. As the ionic liquid is non-volatile and viscous, sealing is not needed. The ionic liquid thickness is estimated to be around 50-100 μm.

Initially the behavior is largely ohmic, but upon charging, it is observed that the device's IV characteristics become like that of an OPV device with efficiency similar to that of OPV devices fabricated with aluminum cathodes.

### Example 2

### Inverted Structured Device

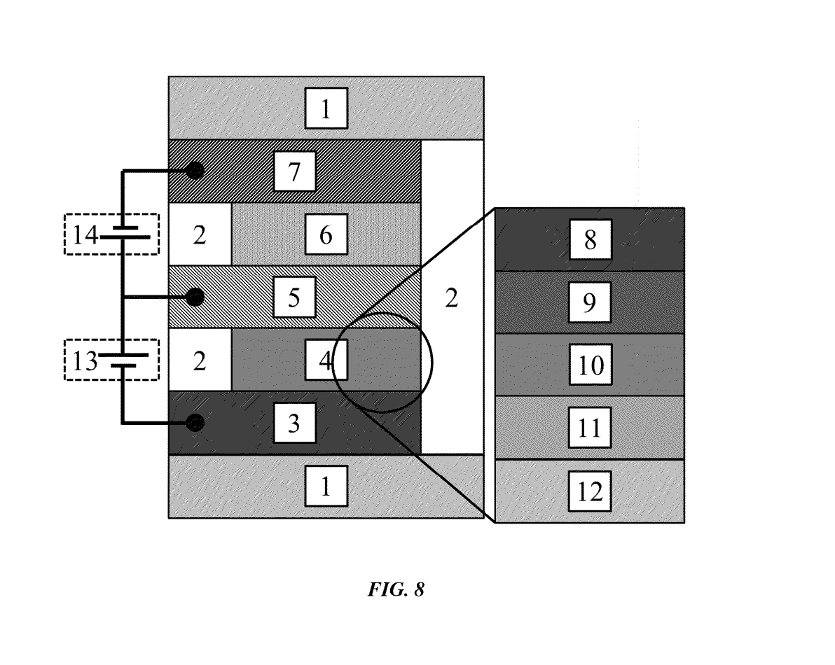

FIG. 8 shows a generalized device structure of an inverted structured device. The inset depicts layers that may be used in this device structure but typical devices may only utilize one of the layers. Voltage may be applied (14) to charge electrodes (5) and (7). Positive voltages will charge electrode (5) n-type and negative voltages will charge electrode (5) p-type.

In an embodiment of the invention, zinc oxide nanoparticles dispersed in butanol were filtered through a 0.45 micron nylon filter and spin-coated onto UV-ozone treated, patterned ITO-glass substrates, resulting in a 15 nm thick layer. The substrates were annealed at 180° C. for five minutes. A 1:1 solution of poly(3-hexylthiophene-2,5-diyl) (P3HT: P200, Rieke Metals Inc.) and phenyl-C61-butyric acid methyl ester (PCBM: Nano-C) in chlorobenzene was then spun onto the PEDOT:PSS substrate, allowed to rest overnight and then annealed at 170° C. for five minutes. The total device thickness was measured to be 200 nm thick by a stylus profilometer.

Highly oriented CNT sheets approximately 3 mm wide were dry-pulled from a CNT forest synthesized at UTD, and laid on top of the P3HT:PCBM layer. After five layers were laid, the carbon nanotubes were densified with 3M™ Novec™ 7100 Engineered Fluid, methoxy-nonafluorobutane (C₄F₉OCH₃). An additional five layers were applied to the bare glass and ITO on the far side of the device to serve as a gate electrode. Contacts were created using silver paint. A drop (˜10 ul) of ionic liquid, N,N-Diethle-N-methyl-N-(2-methoxyethyl)ammonium tetrafluoroborate, DEME-BF4 (Kanto Chemical Co. Inc.), was placed on top of both CNT electrodes. A glass microscope cover-slip was placed on the ionic liquid to spread and contain it. As the ionic liquid is non-volatile and viscous, sealing is not needed. The ionic liquid thickness is estimated to be around 50-100 μm.

IV characteristics are initially like that of an OPV, but can be modulated by charging. In this case P-type charging results in higher current and filling factor. It is also observed that these devices can self-charge under illumination increasing these parameters.

### Example 3

### Other Polymers use in Ionic-OPV

Poly(3,4-ethylenedioxythiophene):poly-(styrenesulfonate) PEDOT:PSS from Heraeus (Clevios™ PVP AI 4083) was filtered through a 0.45 micron nylon filter and spin-coated onto UV-ozone treated, patterned ITO-glass substrates, resulting in a 30 nm thick layer. The substrates were annealed at 180° C. for five minutes. A 1:2 solution of Poly([4,8-bis[(2-ethylhexyl)oxy]benzo[1,2-b:4,5-b′]dithiophene-2,6-diyl}{3-fluoro-2-[(2-ethylhexyl)carbonyl]thieno[3,4-b]thiophenediyl}) (PTB7 1Material Inc.) and phenyl-C71-butyric acid methyl ester (PC₇₁BM: Solenne) in dichlorobenzene was then spun onto the PEDOT:PSS substrate, allowed to rest overnight. The total device thickness was measured to be 100 nm thick by a stylus profilometer.

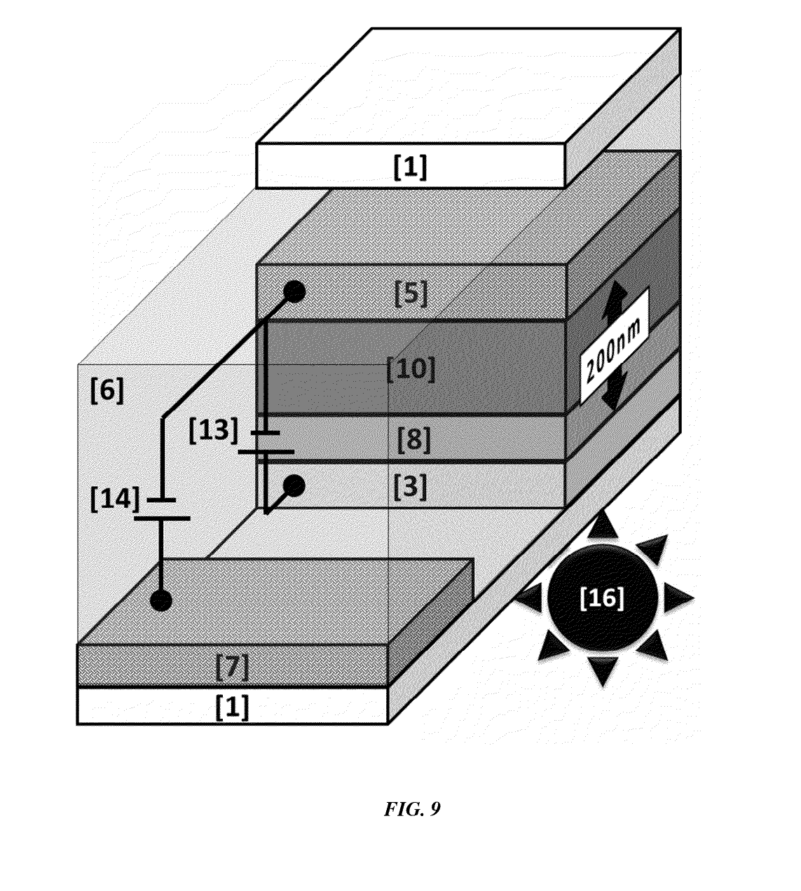

Highly oriented CNT sheets approximately 3 mm wide were dry-pulled from a CNT forest synthesized at UTD, and laid on top of the P3HT:PCBM layer. After five layers were laid, the carbon nanotubes were densified with 3M™ Novec™ 7100 Engineered Fluid, methoxy-nonafluorobutane (C4F9OCH3). An additional five layers were applied to the bare glass and ITO on the far side of the device to serve as a gate electrode. Contacts were created using silver paint. A drop (˜10 ul) of ionic liquid, N,N-Diethle-N-methyl-N-(2-methoxyethyl)ammonium tetrafluoroborate, DEME-BF4 (Kanto Chemical Co. Inc.), was placed on top of both CNT electrodes. A glass microscope cover-slip was placed on the ionic liquid to spread and contain it. As the ionic liquid is non-volatile and viscous, sealing is not needed. The ionic liquid thickness is estimated to be around 50-100 μm. The device is then tested in a standard solar simulator. FIG. 9 depicts a 3D schematic diagram of the described device, with the orientation of the light source of the solar simulator shown.

Initially the behavior is largely ohmic, but upon charging, it is observed that the device's IV characteristics become like that of an OPV device with efficiency similar to that of OPV devices fabricated with aluminum cathodes. Similar results would be found with other polymers, and solid state perovskite cells.

### Example 4

### Small Molecule Ionic-OPV

The substrates were UV-Ozone treated for five minutes and loaded into a high vacuum organics deposition system. Layers of CuPc, C₆₀, and BCP are deposited onto the substrate one after another. The total device thickness was measured to be 75 nm thick by a stylus profilometer.

Highly oriented CNT sheets approximately 3 mm wide were dry-pulled from a CNT forest synthesized at UTD, and laid on top of the P3HT:PCBM layer. After five layers were laid, the carbon nanotubes were densified with 3M™ Novec™ 7100 Engineered Fluid, methoxy-nonafluorobutane (C4F9OCH3). An additional five layers were applied to the bare glass and ITO on the far side of the device to serve as a gate electrode. Contacts were created using silver paint. A drop (˜10 ul) of ionic liquid, N,N-Diethle-N-methyl-N-(2-methoxyethyl)ammonium tetrafluoroborate, DEME-BF4 (Kanto Chemical Co. Inc.), was placed on top of both CNT electrodes. A glass microscope cover-slip was placed on the ionic liquid to spread and contain it. As the ionic liquid is non-volatile and viscous, sealing is not needed. The ionic liquid thickness is estimated to be around 50-100 μm.

As the organic layers intrinsically form a diode, there is initially a diode curve, but there is also a reverse diode effect between the BCP and the carbon nanotubes, resulting in an S-shaped curve. As the device is charged n-type, the curve transitions into a normal diode curve, however at larger negative voltages, breakdown occurs as the semiconducting layers become doped and shunt charges through the device.

### Example 5

### Photodetector or Switchable Diode

Devices are formed as in one of the prior or following examples. However, the device is operated in a reverse bias in which there is a large and linear response to light excitation. If the device is in the regular structure, it may also function as a switchable diode in which the diode behavior is only ‘on’ when the current is applied. Similar behavior can be achieved with an inverted device, but now the diode will be on normally, but applying a positive gate voltage turns the diode off recovering a (photo)resistor-like behavior.

### Example 6

### Single Wall SWCNT as Common Electrode in Ionic-OPV

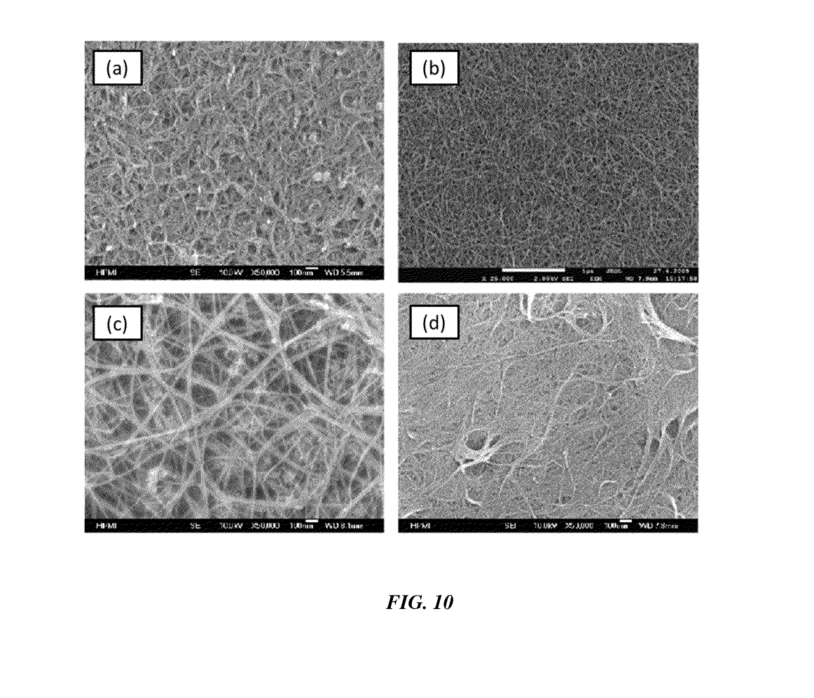

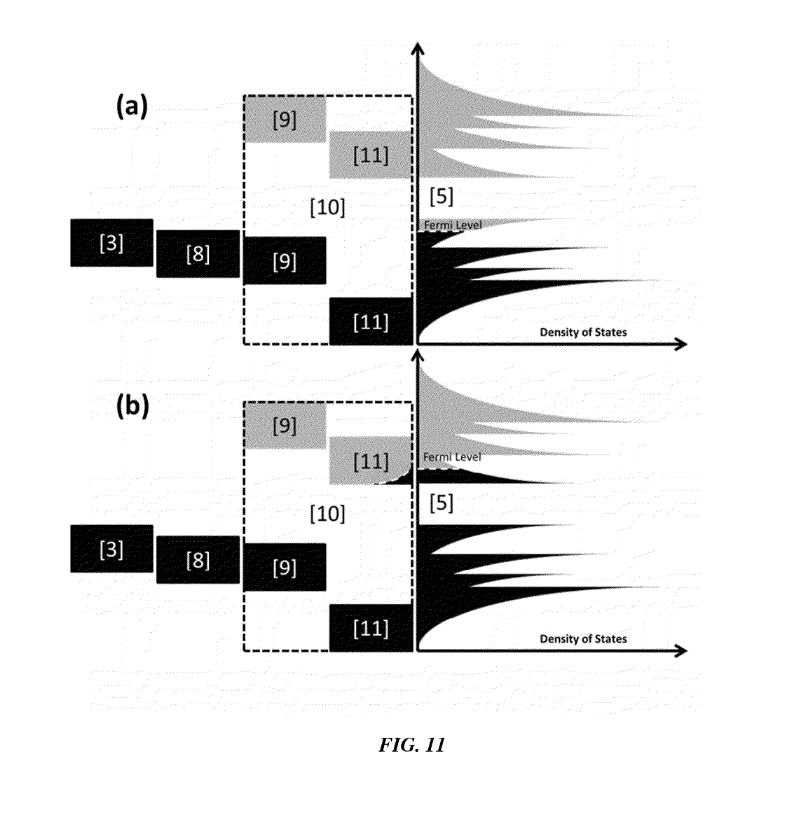

Device semiconducting layers are formed in a method similar to prior examples. Various CNT-based electrodes can be utilized, as shown in FIG. 10, with examples such as a sample of MWCNT bucky paper, Nanoesko SWCNT with small bundles, MWCNT with large bundle size and SWNCT from Nanocomp with larger bundle sizes. Using SWNT as the common electrode is particularly interesting as the unique density of states, which include Van Hove singularities, allow for the hole-doping, and electron-doping of SWNTs during EDLC charging, as shown in FIGS. 11a and 11b respectively. Thus the SWNT can be tuned n-type and p-type with large change in conductivities. Common electrodes are fabricated by lamination of SWCNT films on filter paper onto the device area then removal of the filter by either dissolving the filter in acetone or physically peeling it off. A gate electrode may be fabricated from MWCNT or more SWCNT, as shown in the highly porous CNT structure structures in FIG. 10. Contacts were created using silver paint. A drop (˜10 ul) of ionic liquid, N,N-Diethle-N-methyl-N-(2-methoxyethyl)ammonium tetrafluoroborate, DEME-BF4 (Kanto Chemical Co. Inc.), was placed on top of both CNT electrodes. A glass microscope cover-slip was placed on the ionic liquid to spread and contain it. As the ionic liquid is non-volatile and viscous, sealing is not needed. The ionic liquid thickness is estimated to be around 50-100 μm.

If the device is fabricated in a regular structure, the device shows ohmic behavior prior to charging and increasingly diode like behavior upon charging. With inverted structures, the diode behavior is already present, but increases with p-type charging and decreases with n-type charging. The behavior will be somewhat different from the MWCNT case as the higher surface area and semiconducting SWCNT tubes will result in stronger modulation of work function and resistance upon charging.

### Example 7

### Graphene Nanoribbons as Common Electrode in Ionic-OPV

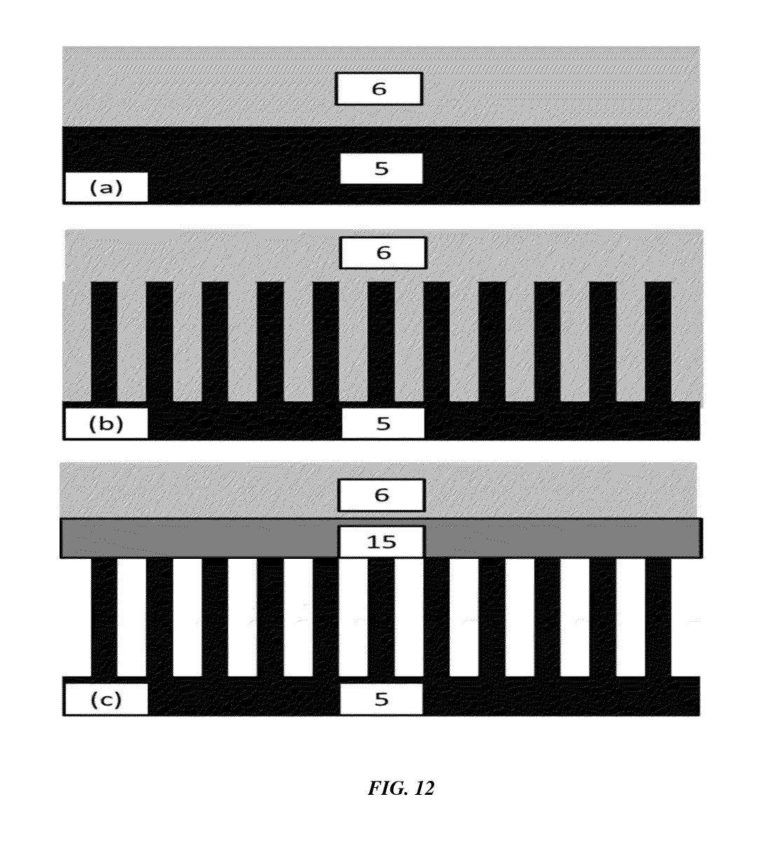

Device semiconducting layers are formed in a method similar to prior examples. Common electrodes are fabricated from either graphene nanoribbons, graphene flakes, or sheets of graphene. A gate electrode may be fabricated from MWCNT or more graphene materials. The underlying characteristic is porosity of the electrodes, FIG. 12(a) depicts a bulk surface which has low surface area exposed to an ionic liquid, which minimizes the EDLC effects on the material. FIG. 12(b) depicts a porous surface with approximately seven times the surface area of (a), in this charge EDLC charging substantially more effective, and finally FIG. 12(c) depicts a porous surface which is capped with an impermeable material closing off all of its surface, no ELDC will occur in this situation. Hence the choice of material for the electrode is critical.

Contacts were created using silver paint. A drop (˜10 ul) of ionic liquid, N,N-Diethle-N-methyl-N-(2-methoxyethyl)ammonium tetrafluoroborate, DEME-BF4 (Kanto Chemical Co. Inc.), was placed on top of both CNT electrodes. A glass microscope cover-slip was placed on the ionic liquid to spread and contain it. As the ionic liquid is non-volatile and viscous, sealing is not needed. The ionic liquid thickness is estimated to be around 50-100 μm.

If the device is fabricated in a regular structure, the device shows ohmic behavior prior to charging and increasingly diode like behavior upon charging. With inverted structures, the diode behavior is already present, but increases with p-type charging and decreases with n-type charging. The behavior will be somewhat different from the MWCNT case as the higher surface area and semiconducting SWCNT tubes will result in stronger modulation of work function and resistance upon charging.

### Example 8

### Gel or Solid State Electrolyte in Ionic-OPV

Device semiconducting layers are formed in a method similar to prior examples. Common and gate electrodes are also formed as discussed previously. Contacts were created using silver paint. A mix of electrolyte and polymer matrix is spun coated onto the device from a mild polar solvent such as ethanol. A glass microscope cover-slip was placed on the ionic liquid to spread and contain it. The device may be sealed to prevent absorption of water and oxygen into the gel material and thus the OPV, but is not needed for testing.

The electrical behavior of the device would be like that of the earlier discussed examples but the device would charge at a significantly slower rate due to the lower mobility of ions in the solid or gel electrolyte.

### Example 9

### Energy Storage in Hybrid Ionic-OPV

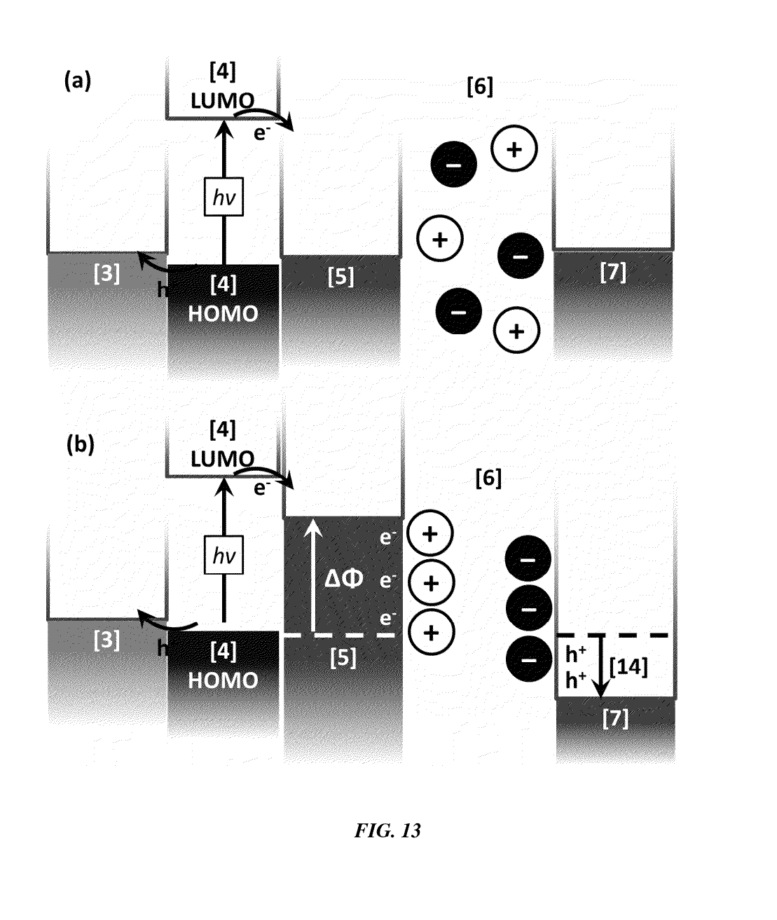

The device is formed and operated in a similar manner as to those discussed above. Before illumination the supercapacitor is uncharged, as shown in FIG. 13a. However, during operation the supercapacitor is either charged intrinsically or is externally switched into a state in which the super capacitor may be charged, as shown in FIG. 13b. When illumination by light ceases, the supercapacitor discharges providing current and current.

### Example 10

### Regular Structure Ionic-OPV Device: Performance Enhancement

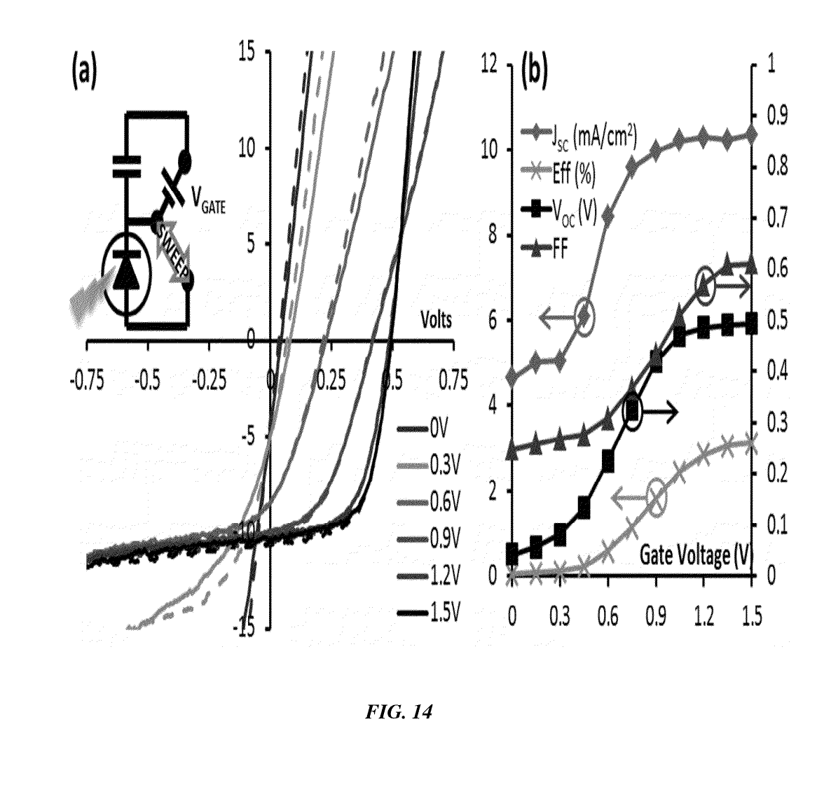

The reconfigurability of the hybrid device is most dramatically found in the OPV IV characteristics. Voltage sweeps from −0.8V to 0.8V and back were performed under AM 1.5G illumination and in the dark. Prior to the inclusion of ionic liquid, the IV characteristics are purely ohmic; i.e. show a linear relation between current and voltage. We reconfigured this symmetric device (which is not an OPV yet) by charging the capacitor, waiting five minutes for stabilization, and then running a set of five sweeps. The findings from the final voltage sweep in each set are shown in FIG. 14a. The results clearly show a good OPV performance, progressing from a ‘hole-only’ photoresistor into a photodiode.

Little change was observed in the IV characteristics before inclusion of ionic liquid and afterwards with a gate voltage of 0V. However, with V_{GATE}=0.3V, we start to see photodiode-like IV characteristics overlaid on the ohmic characteristics. The photodiode behavior becomes stronger and the ohmic character weakens as V_{GATE} increases with a threshold around V_{GATE}=0.4-0.5V. At V_{GATE}=1.5V, the IV characteristics are those of a good photodiode. With moderate gate voltages, we observe some hysteresis in the IV curves; probably from additional charging/discharging of the CNT common electrode from the OPV IV sweep.

The changes of open-circuit voltage (V_{OC}), short-circuit current (J_{SC}), fill-factor (FF), and external efficiency (Eff), derived from FIG. 2a, are plotted as a function of V_{GATE} in FIG. 14b. Below V_{GATE}=0.3-0.4V, the parameters do not increase significantly. Above V_{GATE}=0.5V, a sharp rise in all four values (V_{OC}, I_{SC}, FF, and EFF) occurs. With the exception of FF and EFF, the increases taper off after V_{GATE}=0.9V−1V. We note that the maximum parameters achieved almost match the best regular structured P3HT:PC₆₁BM cell, and that the series resistance in the forward bias of the highly charged state surpasses the series resistance prior to charging.

In the preceding detailed description, the invention is described with reference to specific exemplary embodiments thereof and locations of use within the spine. Various modifications and changes may be made thereto without departing from the broader spirit and scope of the invention as set forth in the claims. The specification and drawings are, accordingly, to be regarded in an illustrative rather than a restrictive sense.

### REFERENCES

1. Panzer M J, Newman C R, Frisbie C D. Low-voltage operation of a pentacene field-effect transistor with a polymer electrolyte gate dielectric. Applied Physics Letters 2005; 86:103503.
2. Panzer M J, Frisbie C D. Polymer Electrolyte Gate Dielectric Reveals Finite Windows of High Conductivity in Organic Thin Film Transistors at High Charge Carrier Densities. J Am Chem Soc 2005; 127:6960-1.
3. Panzer M J, Frisbie C D. High charge carrier densities and conductance maxima in single-crystal organic field-effect transistors with a polymer electrolyte gate dielectric. Applied Physics Letters 2006; 88:203504.
4. Panzer M J, Frisbie C D. High Carrier Density and Metallic Conductivity in Poly(3-hexylthiophene) Achieved by Electrostatic Charge Injection. Advanced Functional Materials 2006; 16:1051-6.
5. Lee J, Panzer M J, He Y, Lodge T P, Frisbie C D. Ion Gel Gated Polymer Thin-Film Transistors. J Am Chem Soc 2007; 129:4532-3.
6. Panzer M J, Frisbie C D. Polymer Electrolyte-Gated Organic Field-Effect Transistors: Low-Voltage, High-Current Switches for Organic Electronics and Testbeds for Probing Electrical Transport at High Charge Carrier Density. J Am Chem Soc 2007; 129:6599-607.
7. Panzer M J, Frisbie C D. Exploiting Ionic Coupling in Electronic Devices: Electrolyte-Gated Organic Field-Effect Transistors. Advanced Materials 2008; 20:3177-80.
8. Fujimoto, T.; Suizu, R.; Yoshikawa, H.; Awaga, K. Chem. Eur. J. 2008, 14, 6053-6056, Page 14 of 16
9. Fujimoto, T.; Matsushita, M. M.; Yoshikawa. H.; Awaga, K. J. Am. Chem. Soc. 2008, 130, 15790-15791.
10. Fujimoto, T.; Matsushita, M. M.; Awaga, K. Chem. Phys. Lett. 2009, 483, 81-83.
11. Fujimoto, T.; Matsushita, M. M.; Awaga, K. Appl. Phys. Lett. 2010, 97, 123303.
12. Fujimoto, T.; Matsushita, M. M.; Awaga, K. J. Phys. Chem. C 2012, 116, 5240-5245.
13. Miyoshi, Y.; Fujimoto, T.; Yoshikawa, H.; Matsushita, M. M.; Awaga, K.; Yamada, T.; Ito, H. Org. Electron. 2011, 12, 239-243.
14. Fujimoto, T.; Miyoshi, Y.; Matsushita, M. M.; Awaga, K. Chem. Commun. 2011, 47, 5837-5839.
15. Miyoshi, Y.; Takahashi, K.; Fujimoto, T.; Yoshikawa, H.; Matsushita, M. M.; Ouchi, Y.; Kepenekian, M.; Robert, V.; Donzello, M. P.; Ercolani, C.; Awaga, K. Inorg. Chem. 2012, 51, 456-462.
16. Li B, Noda Y, Hu L, Yoshikawa H, Matsushita M M, Awaga K. Highly efficient organic optoelectronic conversion induced by electric double layers in ionic liquids. Applied Physics Letters 2012; 100:163304.
17. Shimotani, H.; Suzuki, H.; Ueno, K.; Kawasaki, M.; Iwasa, Y. Appl. Phys. Lett. 2008, 92, 242107.
18. Yuan, H. T.; Shimotani, H.; Tsukazaki, A.; Ohtomo, A.; Kawasaki, M.; Iwasa, Y. Adv. Funct. Mater. 2009, 19, 1046-1053
19. Ye, J. T.; Inoue, S.; Kobayashi, K.; Kasahara, Y.; Yuan, H. T.; Shimotani, H.; Iwasa, Y. Nature Mater. 2010, 9, 125-128.
20. Okimoto, H.; Takenobu, T.; Yanagi, K.; Miyata, Y.; Shimotani, H.; Kataura, H.; Iwasa, Y. Adv. Mater. 2010, 22, 3981-3986.
21. Yamada, Y.; Ueno, K.; Fukumura, T.; Yuan, H. T.; Shimotani, H.; Iwasa, Y.; Gu, L.; Tsukimoto,
22. Kugler T. Electrolyte pattern and method for manufacturing an electrolyte pattern. 7927913, 2011.
23. Kugler T. Transistor. 8022397, 2011.
24. Frisbie C D, Lodge T P. Ion gels and electronic devices utilizing ion gels. 7999020, 2011.
25. Osterbacka R, Wilen C-E, Backlund T, Kaihovirta N. Organic Field-Effect Transistor, n.d.
26. Dasgupta S, Hahn H, Kruk R. Electrochemically-gated transistor and a method for its manufacture. WO2012025190 A1, 2012.
27. Yang Y, Li S, Ma L. Ambipolar Vertical Organic Field-Effect Transistors. WO/2007/048041, 2007.
28. Dasgupta S, Hahn H, Kruk R. Electrochemically-gated transistor and a method for its manufacture. WO2012025190 A1, 2012.
29. Kugler T. Electrochemical thin-film transistor. US20090040587 A1, 2009.
30. Suh D-S, Baughman R H, Zakhidov A A. Material and device properties modification by electrochemical charge . . . 7897030, 2011.
31. Zakhidov A A, Suh D-S, Kuznetsov A A, Barisci J N, Muñoz E, Dalton A B, et al. Electrochemically Tuned Properties for Electrolyte-Free Carbon Nanotube Sheets. Advanced Functional Materials 2009; 19:2266-72.
32. Rinzler A G, Wadhwa P, Guo J, Seol G. Electronic gate enhancement of schottky junction solar cells. US20120312371 A1, 2012.

What is claimed is:

1. A multi-junction hybrid device, wherein the device combines an ionic component and a solid organic component and comprises a first electrode, a second electrode and a third electrode, wherein the first electrode is attached to an organic component of the hybrid device for collecting electronic charge carriers of one type, wherein the second electrode is a common electrode for both the organic and ionic components of the hybrid device, and is highly permeable to ions and possesses electronic conductivity, and wherein the third electrode plays a role of a gate electrode for tuning the properties of the second electrode and organic material adjacent to the second electrode by ionic EDLC.

2. The device of claim 1, wherein the second electrode is a tunable highly porous charge collector which is placed between solid part of device and the ionic component, and is highly permeable for ions penetration from the ionic component upon applied to gate voltage.

3. The device of claim 1, wherein the first electrode is an electronic charge collecting electrode that is connected to the solid component, and further wherein the first electrode is optically transparent for various photonic applications.

4. The device of claim 1, wherein the third electrode is a counter-electrode within the ionic component of the device, and further wherein the third electrode is composed of a highly porous nanostructured material and is highly permeable to ions

5. The device of claim 1, wherein the portion of the device between the first electrode and the second electrode is composed of a plurality of solid layers, wherein the solid layers function for photogeneration, transport and collection of electronic charges by the first and second electrodes.

6. The device of claim 1, wherein the portion of the device between the second electrode and the gate electrode is filled with mobile ionic components such as ionic liquids or ionic gels that allow the redistribution of ions and formation of ionic EDLC upon application of gate voltage between the second electrode and the gate electrode.

7. The device of claim 1, wherein the first electrode is a first glass or plastic layer that is coated with a transparent conductor such as a conductive oxide or a optically transmissive electrode.

8. The device of claim 7, further comprising layers of an organic photovoltaic component that is layered on top of the transparent conductor-coated layer.

9. The device of claim 8, wherein the second electrode is a nanoporous charge collecting layer such as a nanotube or nanowire network with a large interfacial area that contacts the layers of the organic photovoltaic component.

10. The device of claim 9, further comprising an ionic component that is layered over the nanoporous charge collecting layer such that the nanoporous layer forms an open porosity nanoporous interconnect between the organic photovoltaic component and the ionic component.

11. The device of claim 10, further comprising a second glass or plastic layer that is coated with a transparent conductor and layered on top of the ionic component.

12. The device of claim 11, further comprising a sealing gasket that connects the first glass or plastic layer and the second glass or plastic layer and prevents the leakage of the ionic component out of the device.

13. The device of claim 7, wherein a charge selective layer is located on top of the first glass or plastic layer coated with transparent conductor in order to invert the charge collection properties of first electrode.

14. The device of claim 10, wherein the nanoporous charge collecting layer acting as second electrode functions as a common cathode and collects electrons from the organic photovoltaic component and collects ions from the ionic component forming EDLC.

15. The device of claim 10, wherein the nanoporous charge collecting layer acting as a common second electrode functions as a common anode and collects holes from the organic photovoltaic component which has an inverted first electrode.

16. The device of claim 13, wherein the charge selective layer blocks the passage of electrons and allows passage of holes.

17. The device of claim 13, wherein the charge selective layer allows the passage of electrons and blocks the passage of holes.

18. The device of claim 10, wherein the nanoporous charge collecting layer acting as a second common electrode is charged negatively and attracts positive ions from the ionic component after photoexcitation or upon application of a proper gate voltage between the second and third electrodes.

19. The device of claim 10, wherein the nanoporous charge collecting layer acting as a common second electrode is charged positively and attracts negative ions from the ionic component after photoexcitation or upon application of a proper gate voltage between the second and third electrodes.

20. The device of claim 10, wherein the nanoporous charge collecting layer acting as a second common electrode comprises a high interface porous conductive nanogrid that is permeable to ions.

21. A multi-junction hybrid solar device, the device comprising:
a transparent conductive oxide layer that is patterned on a transparent substrate;
a charge selective layer that contacts the TCO layer;
an active layer that contacts the charge selective layer and comprises an electron donor and an electron acceptor;
a nanoporous charge collecting common second electrode layer with large interfacial area that is placed on top of the active layer; and
an ionic layer that contacts the nanoporous charge collecting common second electrode layer and the photoactive layer.

22. The device of claim 21, wherein the electron donor and electron acceptor are formed as a bilayer junction.

23. The device of claim 21, wherein the electron donor and electron acceptor are co-deposited to form a bulk heterojunction photoactive layer.

24. The device of claim 21, wherein the nanoporous common second electrode layer comprises a high interface porous conductive nanogrid that is highly permeable to ions.
